(19) United States
(12) Patent Application Publication
(10) Pub. No.: US 2007/0232014 A1
(43) Pub. Date: Oct. 4, 2007

(54) Method of fabricating a planar MIM capacitor

(75) Inventors: Bradley J. Larsen, Mound, MN (US); Jerry Yue, Roseville, MN (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 11/396,844

(22) Filed: Apr. 3, 2006

(51) Int. Cl. H01L 21/20

(52) U.S. Cl. 438/393; 257/E21.021

(57) ABSTRACT

A method of fabricating a Metal-Insulator-Metal (MIM) capacitor is presented. The method includes depositing a bottom plate of the MIM capacitor on a passivating dielectric layer which may be a pre-metal or post metal dielectric layer. A capacitor dielectric of the MIM capacitor is subsequently deposited on top of the bottom plate. The capacitor dielectric and the bottom plate both conform to the profile of the passivating dielectric layer. In addition, because the bottom plate is located on a dielectric, which is thermally stable and does not morph or change significantly with successive thermal processing, the capacitor dielectric does not have to be designed to compensate for topography changes due to such thermal processing.

### FIELD

The present invention relates generally to the field of Metal-Insulator-Metal (MIM) capacitors and more particularly to a method of fabricating a MIM capacitor.

### BACKGROUND

Metal-Insulator-Metal (MIM) capacitors are commonly used in RF CMOS and BiCMOS applications. MIM capacitors are used in these applications because of their very good voltage and temperature-coefficient characteristics. Some example devices that MIM capacitors are used for are decoupling capacitors (for reducing transient currents), RF coupling and RF bypass capacitors (in high frequency oscillator and resonator circuits and in matching networks), filter and analog capacitors (in high performance mixed-signal products, e.g. A/D or D/A converters), and storage capacitors in DRAM and embedded DRAM/logic devices. In addition, MIM capacitors may be included as an added capacitance in SRAM cells to reduce soft error upsets.

Generally, MIM capacitors are located in an interconnect stack. An interconnect stack includes contacts, metal interconnect layers, and vias which are used to electrically couple devices located below the interconnect stack together as well as to provide a coupling of the MIM capacitors to devices outside of a chip.

The interconnect stack, as defined in this disclosure, includes all of the layers that are fabricated subsequent to the last pre-metal passivation layer being deposited. Furthermore, a line of demarcation between front-end processing and back-end processing is created when the first metal layer is deposited in a fabrication process. Front-end processing is generally more tolerant to high temperatures (e.g., annealing and deposition temperatures greater than 450° C.) and extreme chemistries (e.g., sulfuric acid, hydrofluoric acid, SC-1, SC-2, etc.). Because metal layers are included in back-end processing, they are not tolerant to such high temperatures or extreme chemistries.

Using back-end fabrication techniques, a process flow for fabricating a MIM capacitor in an interconnect stack is presented in FIGS. 1A and 1B. FIG. 1A is a prior art method 10 of fabricating a MIM capacitor. FIG. 1B illustrates the creation of the layers of a MIM capacitor by the application of method 10. At the first block of method 10, block 12, a passivation layer 14 is provided. This passivation layer is the last passivation layer deposited or grown prior to a metal layer being deposited. Generally, passivation layer 14 includes tungsten (W) plugs (not shown) which are used as “contacts” to devices located below the passivation layer 14.

At block 16, a metal layer (bottom plate) 18, a capacitor dielectric 20, and a top plate 22 are each deposited on top of passivation layer 14. Because metal layer 18 is present, the choices for deposition processes for capacitor dielectric 20 are limited. For example, if metal layer 18 is aluminum, deposition or anneal temperatures greater than 450° C. may cause metal layer 18 to morph, which may result in a reduction of yield and the integrity and reliability of a MIM capacitor. Additionally, even lower temperatures (i.e., temperatures at or below 450° C.), may create grain growth in metal layer 18 which will reduce the integrity of the capacitor dielectric 20. Because such grain growth may be unpredictable in nature and because it produces a degree of non-linearity in the interface between the metal layer 18 and the capacitor dielectric 20, the thickness of capacitor dielectric 20 may need to be designed to be thick enough to compensate for both of these issues.

Unfortunately, as the thickness of the capacitor dielectric increases, the capacitance of the MIM capacitor also decreases. To counteract a thickness increase, the area of a MIM capacitor may need to be increased. This too is problematic as real estate in a given chip may not be available for a larger MIM capacitor. In addition, increasing the area of MIM capacitor may result in a further decrease in yield and reliability.

Returning to FIG. 1A, the metal layer 18, capacitor dielectric 20, and top plate 22 are etched, as shown at block 24. This may be performed using conventional photolithography and a “wet” or “dry” etch (such as a reactive ion etch). In order to determine the size, or area, of a MIM capacitor, the capacitor dielectric 20, and top plate 22 are etched, as shown at block 26. This may also be performed using conventional photolithography and etching techniques. This etch must be selective to metal layer 18 insuring the layer remains intact for subsequent contacting. MIM capacitor 27 is formed upon completion of block 26.

At block 28, an Inter-Level Dielectric (ILD) layer 30 is deposited on top of MIM capacitor 27. ILD layer 30 surrounds MIM capacitor 27. After its deposition, ILD layer 30 is planarized using CMP, shown at block 31.

At block 32, via holes are etched, filled with a conductive layer, and the over fill removed with a Chemical Mechanical Polish (CMP). Another unfortunate aspect of current MIM capacitor fabrication methods relates to this via hole etch process. Because metal layer 18 may be non-uniform, capacitor dielectric 20 and top plate 22 are also non-uniform. As a result of this non-uniformity, a via hole may become over-etched. Even if the via etch process includes end point detection, thicker MIM capacitors (having a thinner ILD layer above their respective top plates) will be etched for the same amount of time as thinner MIM capacitors (having a thicker ILD layer above their respective top plates). As a result, thicker MIM capacitors will have their respective top plates etched into. In some instances this may result in etching completely through portions of the plate 22, as is shown by over-etch damage 34. When the via hole is filled, vias 38 and 40 are created. Because via 38 is in electrical contact with over-etch damage 34, however, MIM capacitor 27 might fail.

Therefore, there is a need for a MIM capacitor and a method of fabrication that produces MIM capacitors with increased reliability and integrity at higher yields.

### SUMMARY

A method of fabricating a metal-insulator-metal (MIM) capacitor is presented. The MIM capacitor may be fabricated in an interconnect stack. The method includes providing a substrate that includes a dielectric layer that has been planarized. A bottom plate is deposited on top of the planarized dielectric. The planarized dielectric layer includes a contact, or a via, that is located below the bottom plate. The bottom plate, as a result of being deposited on the planarized dielectric, has a flat contour or profile. A capacitor dielectric, which serves as the dielectric of the MIM capacitor, is deposited on top of the bottom plate. The capacitor dielectric may be thin and does not require a compensating thickness that may be required when the bottom plate is on top of a non-planarized and non-dielectric material, such as aluminum or copper.

In another example, a top plate of the MIM capacitor is deposited on top of the capacitor dielectric. A metal layer may then be deposited on top of the top plate. Because the metal layer is deposited after the capacitor dielectric, the capacitor dielectric may be created during a high temperature process. This capability also allows the possibility of a low temperature deposition, such as Atomic Layer Deposition (ALD) followed by a high temperature anneal. The metal layer may be used to provide an electrical coupling to the top plate. The metal layer may be further coupled to a via. The via provides an electrical coupling to other metal layers located above the MIM capacitor. In even further examples this via may be copper. In addition to providing an electrical coupling to the via, the metal layer may protect the top plate as well as the MIM capacitor during an over-etch of a via hole that contains the via.

These as well as other aspects and advantages will become apparent to those of ordinary skill in the art by reading the following detailed description, with reference where appropriate to the accompanying drawings. Further, it is understood that this summary is merely an example and is not intended to limit the scope of the claims.

### BRIEF DESCRIPTION OF THE DRAWINGS

Certain examples are described below in conjunction with the appended drawing figures, wherein like reference numerals refer to like elements in the various figures, and wherein:

FIG. 1A is a flow diagram of a prior art method of fabricating a Metal-Insulator-Metal (MIM);

FIG. 1B contains sequential cross-sectional diagrams illustrating the application of the flow diagram of FIG. 1A;

FIG. 2A is a flow diagram of a method of fabricating a MIM capacitor;

FIG. 2B contains sequential cross-sectional diagrams illustrating the application of the flow diagram of FIG. 2A;

FIG. 2C is a cross-section of a bottom plate surrounded by a capacitor dielectric; and

FIGS. 2D-G contain cross-sections of various MIM capacitors.

### DETAILED DESCRIPTION

A method of fabricating a MIM capacitor is presented. The method includes depositing a bottom plate of a MIM capacitor on top of a planarized dielectric layer. The planarized dielectric may be the last pre-metal dielectric layer in a fabrication process, or an ILD layer. Because the bottom plate is deposited on a planarized surface and because the planarized dielectric layer is a more stable film (when compared to a metal film), a more uniform bottom plate, top plate, and capacitor dielectric of the MIM capacitor may be produced. In addition, the capacitor dielectric may be thinner than a MIM capacitor manufactured using conventional methods of fabrication. Advantages associated with producing thin uniform capacitor dielectrics and advantages of producing such dielectrics prior to metal layer deposition are described below.

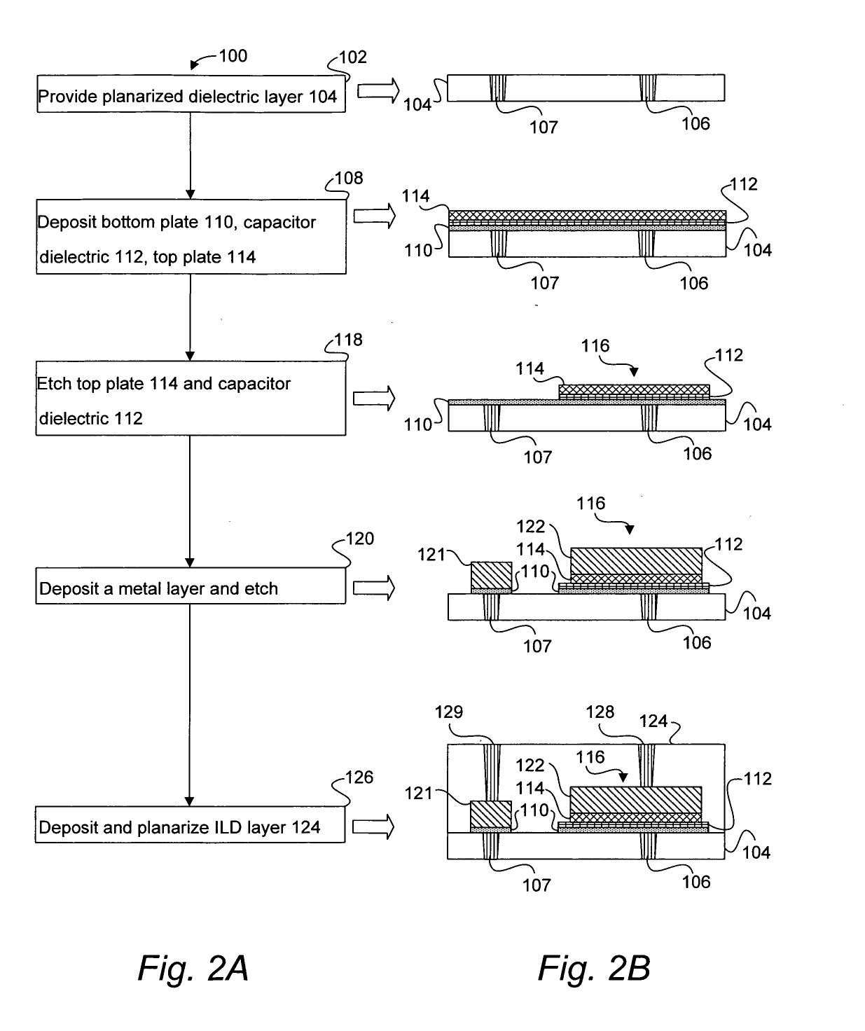

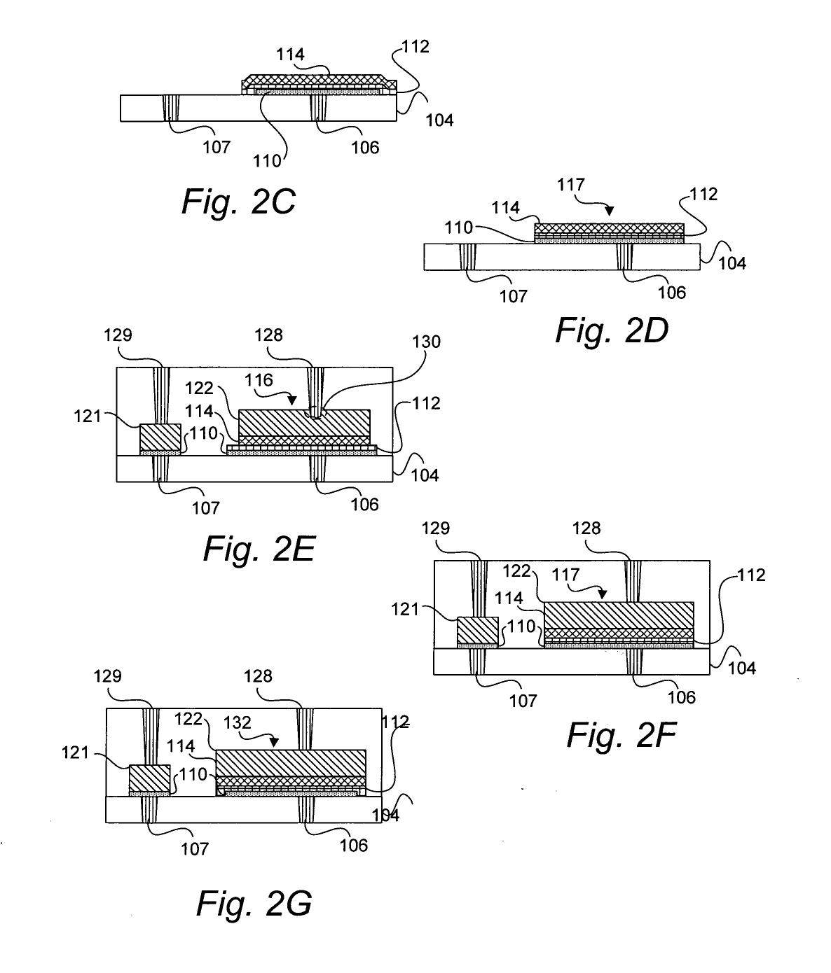

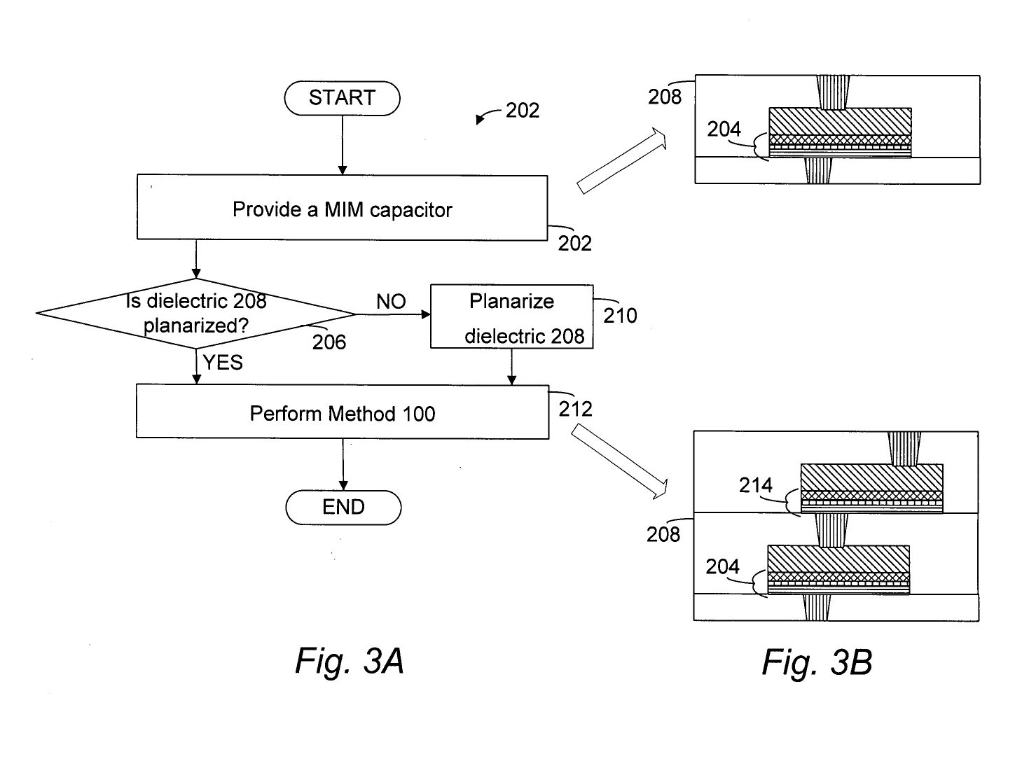

Turning now to FIGS. 2A and 2B, a method 100 of fabricating a MIM capacitor is presented. At block 102, a planarized dielectric layer 104 is provided. In some examples, dielectric layer 104 may be a pre-metal dielectric layer. Alternatively, layer 104 may be a post-metal dielectric layer. Planarization of dielectric layer 104 may be achieved by CMP, for example

In addition to being planarized, dielectric layer 104 should be selected so that it does not substantially change in topography during thermal processing. Minimizing or eliminating such a topography change will also minimize or eliminate topography changes of the capacitor dielectric within a MIM capacitor. As described above, metals and other similar types of materials may have unpredictable or undesirable thermal properties. These thermal properties relate to grain structures and grain growth which may directly impact the topography of the capacitor dielectric.

Returning to FIG. 2B, dielectric layer 104, as shown, may be referred to as a passivation layer, in that it protects devices and structures within it and it provides electrical isolation from elements located within, above, and below it. Also shown within dielectric layer 104 are vias 106 and 107. Via 106 may be used to couple a MIM capacitor formed on top of dielectric layer 104 to devices or electrical connections located below dielectric layer 104. Vias 106 and 107 may also be a contact to devices formed in front end processing. Such devices include MOS transistors, capacitors, resistors, Micro Electronic Mechanical Structures (MEMS), etc. For example, via 106 and/or 107 may provide an electrical coupling to a silicided region of a poly-silicon gate of a MOS transistor.

At block 108, a bottom plate 110, a capacitor dielectric 112, and a top plate 114 are deposited. The bottom plate 110 and top plate 114 may be Ti, TiN, TiW, or other types of bottom and top plate materials. Other such “liner” materials and their deposition processes may also be used. The bottom plate 110 conforms to the planar surface of the dielectric layer 104. In addition, the bottom plate 110 may be etched prior to the deposition of capacitor dielectric 112 and top plate 114. If this is the case, bottom plate 110 will be enclosed within capacitor dielectric 112 and it may allow subsequent metal layers to pass over the bottom plate 110 without shorting to that bottom plate. FIG. 2C shows an example of an etched bottom plate 110 located beneath and enclosed by capacitor dielectric 112.

Capacitor dielectric 112 may be deposited in a wide variety of processes that provide a film that conforms to the surface of bottom plate 110. In effect, the uniformity or degree of planarity that capacitor dielectric 112 has may be attributed to dielectric layer 104. A Chemical Vapor Deposition (CVD) or a Plasma Enhanced CVD (PECVD) process may be used to create capacitor dielectric 112, for example. In addition, non-conventional processes, not normally used in MIM capacitor fabrication may be used. Atomic Layer Deposition (ALD), for example, may provide a thin, uniform dielectric.

ALD, as is known in the art, may use similar chemistries to that of a CVD process; however, ALD breaks the CVD reaction into two half-reactions, keeping precursor materials separate during the reaction. Because ALD film growth is self-limited and based on surface reactions, atomic scale deposition control is possible. ALD is typically not compatible with back-end processing because it includes a high temperature cure. However, if no metal layer has been deposited subsequent to the formation of capacitor dielectric 112, capacitor dielectric 112 may be formed by such an ALD process. As a result, a high capacitance per unit area may be achieved.

In addition to the various types of deposition processes that may be used to create capacitor dielectric 112, a variety of dielectric materials may be used for capacitor dielectric 112. Materials such as Al₂O₃, SiO₂, SiN, and Si₃N₄ may be selected for capacitor dielectric 112. In addition, other higher dielectric materials, such as Ta₂O₅ and HfO₂, may be used.

After bottom plate 110, capacitor dielectric 112, and top plate 114 are formed, capacitor dielectric 112 and top plate 114 are etched, forming an area of MIM capacitor 116, as shown at block 118. In the example of FIG. 2B, the etch stops on bottom plate 110. As an alternative example, however, a MIM capacitor 117 may be “self-aligned” in a single etch (i.e., bottom-plate 110, capacitor dielectric 112, and top plate 114 are etched in a single etch). This is shown in FIG. 2D. In either case, capacitor dielectric 112 should be removed from above via 107, or else subsequent metal layers may not be able to make contact with via 107.

After MIM capacitor 116 is formed, a metal layer is deposited and etched, as shown at block 120. Also etched is bottom plate 110 and top plate 114. The metal layer is patterned so that it provides a metal line 121 above via 107 and a top plate coupling 122 to top plate 114. During the metal etch, the bottom plate 110 is aligned with the capacitor dielectric 112. Also during the metal etch, the top plate 114 and the top plate coupling 122 are aligned to a photoresist mask. It should be understood that a wide variety of photo resists, developers, Anti-Reflective Coatings (ARCs), and etches may be used to achieve a desired shape or area of MIM capacitor 116. In addition, multiple metal etches may be from metal line 121 and top plate coupling 122. For instance, a first metal etch may create metal line 121. Then, metal line 121 may be masked and a second metal etch may create top plate coupling 122.

After the metal layer is etched, an ILD layer 124 is deposited on top of MIM capacitor 116 and planarized as shown at block 126. This may performed in a similar fashion to blocks 28 and 31 in method 10. The ILD layer 124 may surround both MIM capacitor 116 and metal line 121. Vias 128 and 129 may be formed through the ILD layer 124. The via 128 may provide an electrical coupling to the top plate coupling 122. The top plate coupling 122, in turn provides an electrical coupling to the top plate 114. The metal layer may be any type of metal that is used for interconnecting devices located in an interconnect layer, such as aluminum or copper. Vias 128 and 129 may also be a known type of material, such as tungsten or copper. Because capacitor dielectric 112 is formed prior to the top plate coupling 122 and vias 128 and 129 all of these materials may be copper. Generally, this would not be possible if the metal layer was deposited before capacitor 116 because of front-end and back-end non-compatibility.

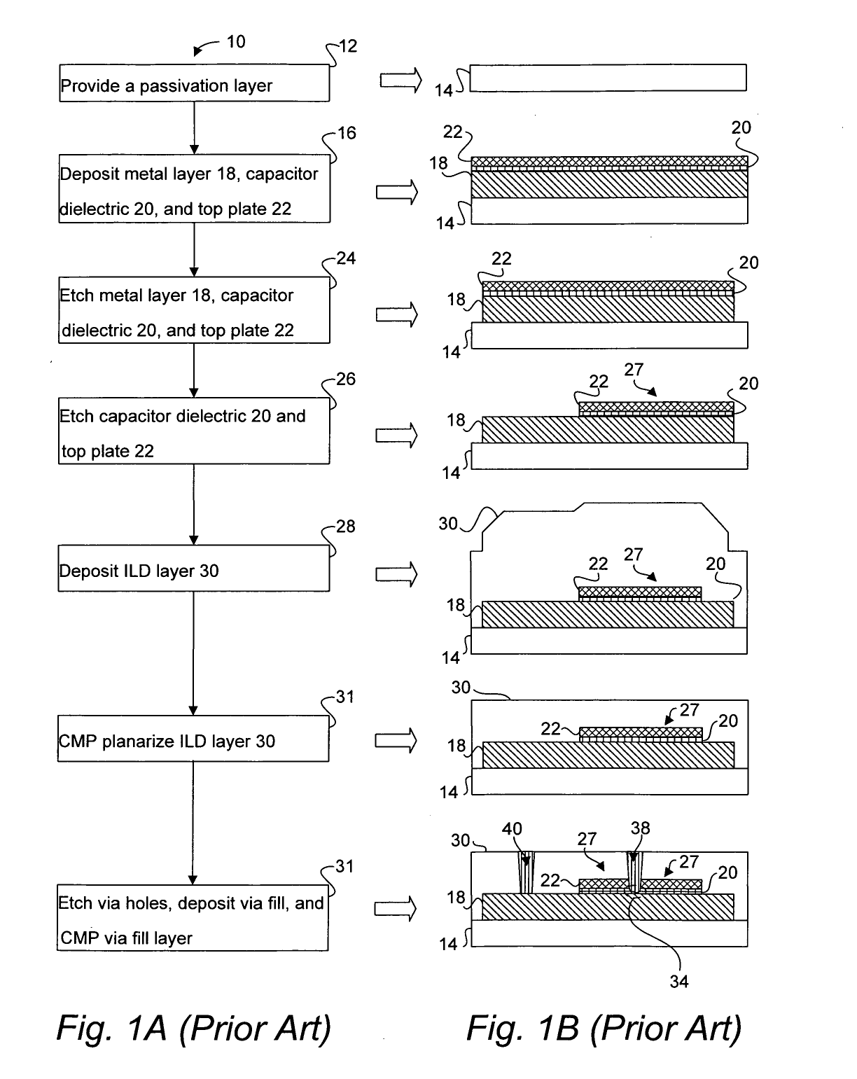

It should also be noted that the via hole used for via 128 may be overetched without reducing yield or the reliability and integrity of the MIM capacitor 116. For example, FIG. 2E shows an over-etch that creates a small trench 130 in top plate coupling 122. Because top plate coupling 122 is thick (when compared to top plate 22 shown in FIG. 1B), the via hole will not penetrate top plate 114. Top plate coupling 122, therefore, protects top plate 114 and MIM capacitor 116 during such a via hole over-etch. Depending on the composition of the etch and the composition of the metal layer a via is landing on, a via over-etch may trench into a metal layer anywhere from 50 to 1000 angstroms.

Although the method 100 has been described for creating a single MIM capacitor, multiple MIM capacitors may be created by application of method 100 once, or multiple times. Numerous MIM capacitors may be created in a single interconnect layer at the same time, for example. Alternatively, a MIM capacitor may be included in each interconnect layer of a fabrication process.

The presented methods, when carried out, provide a MIM capacitor having a uniform capacitor dielectric. MIM capacitor 116 is one such example. MIM capacitors 117 and 132, respectively shown in FIGS. 2F and 2G are other alternative examples. MIM capacitor 117 is a self-aligned capacitor under an ILD. MIM capacitor 132, on the other hand, is created using a buried bottom plate 110 (shown in FIG. 2C). All of these capacitors have a uniform capacitor dielectric that is not limited by the film that their respective bottom plates are deposited on. Instead, the bottom plate is deposited on a passivation layer that is a dielectric material and not a metal. A metal, such as aluminum, may have a grain structure and grain growth which may produce limitations to the capacitor dielectric. The passivation layer, being that is made from the dielectric material may have a low thermal expansion coefficient.

Overall, it should be understood that the illustrated examples are examples only and should not be taken as limiting the scope of the present invention. For example, the term “deposited” is used generically to refer to the known growth, CVD, PECVD, ALD, and other methods of fabricating dielectric, metal, and other semiconductor related films. In addition, the term “bottom plate” generally refers to a layer immediately below a capacitor dielectric and the term “top plate” generally refers to the layer immediately above the capacitor dielectric. However, the bottom and top plates may include additional metal layers located either above a top plate or below a bottom plate. The claims should not be read as limited to the described order or elements unless stated to that effect. Therefore, all examples that come within the scope and spirit of the following claims and equivalents thereto are claimed as the invention.

We claim:

1. A method of fabricating a Metal-Insulator-Metal (MIM) capacitor in an interconnect stack, the method comprising:
planarizing a top surface of a first dielectric layer, the dielectric layer including a first via for providing an electrical coupling through the first dielectric layer;
depositing a bottom plate of the MIM capacitor on top of the via and the top surface of the first dielectric layer, the bottom plate conforming to the top surface of the first dielectric layer;
depositing a second dielectric layer on a top surface of the bottom plate, the second dielectric conforming to the top surface of the bottom plate, and a material of the first dielectric layer being chosen so that a topography associated with the second dielectric layer does not change during subsequent thermal processing.

2. The method as in claim 1, further comprising:
prior to depositing the second dielectric layer, etching the bottom plate.

3. The method as in claim 2, wherein the second dielectric layer surrounds the bottom plate and provides electrical isolation for the bottom plate.

4. The method as in claim 1, further comprising:
etching the second dielectric layer so as to define an area associated with the MIM capacitor.

5. The method as in claim 1, further comprising:
depositing a top plate of the MIM capacitor on a top surface of the second dielectric layer.

6. A metal-insulator-metal (MIM) capacitor formed in an interconnect stack, comprising:
a bottom plate located on top of a first electrical contact surrounded by a passivation layer, the first electrical contact and the passivation layer each having a surface that is planar; and
a dielectric layer located on top of the bottom plate, the dielectric layer having a uniformity that is attributed to the planar surface of the passivation layer, and the passivation layer being chosen so as to reduce a topography change of the dielectric layer during thermal processing.

7. The MIM capacitor as in claim 6, further comprising a top plate located on top of the dielectric layer, the top plate being located beneath a second electrical contact that provides an electrical coupling to the top plate.

8. The MIM capacitor as in claim 6, wherein the second electrical contact is copper.

9. The device as in claim 6, wherein the dielectric layer is deposited in an Atomic Layer Deposition (ALD) process.

10. A method of fabricating a metal-insulator-metal (MIM) capacitor in an interconnect stack, the method comprising:
providing a substrate that includes a planar dielectric layer and a first via, the first via for providing an electrical coupling through the first dielectric layer; and
depositing a bottom plate of the MIM capacitor on top of an exposed portion of the first via, the bottom plate of the MIM capacitor having a flat contour that is attributed to the planar dielectric layer.

11. The method as in claim 10, further comprising:
depositing a second dielectric layer on top of the bottom plate, the second dielectric layer being located in between the bottom plate and a top plate of the MIM capacitor.

12. The method as in claim 11, wherein the second dielectric layer is a material selected from the group consisting of Al₂O₃, Ta₂O₅ and HfO₂.

13. The method as in claim 11, further comprising:
exposing the substrate to a thermal cycle, the flat contour of the second dielectric layer being maintained as a result of a low thermal expansion coefficient associated with the planar dielectric layer.

14. The method as in claim 11, wherein depositing the second dielectric layer is performed by an Atomic Layer Deposition (ALD) process.

15. The method as in claim 11, further comprising depositing the top plate of the MIM capacitor on top of the second dielectric layer.

16. The method as in claim 15, further comprising etching the second dielectric layer, thereby establishing a capacitance value of the MIM capacitor.

17. The method as in claim 16, further comprising:
depositing a metal layer on top of the top plate; and
etching the metal layer so as to form an electrical coupling to the top plate, the metal layer preventing a critical area associated with the top plate from being etched during a subsequent via hole etch.

18. The method as in claim 17, wherein the top plate is etched during the etch of the metal layer and the etch of the metal layer stops on the second dielectric layer.

19. The method as in claim 17, further comprising:
depositing a third dielectric layer on top of the metal layer;
planarizing the third dielectric layer; and
forming a second via in the third dielectric layer, the second via providing an electrical coupling through the third dielectric layer to the metal layer.

20. The method as in claim 10, wherein the first via is a contact, the contact providing an electrical coupling to a device fabricated in a front-end process.
